(19) United States
(12) Patent Application Publication
(10) Pub. No.: US 2025/0062125 A1
(43) Pub. Date: Feb. 20, 2025

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventors: Gyeong Won SONG, Cheonan-si (KR); Hee Man AHN, Seoul (KR); Sung Hun EOM, Hwaseong-si (KR); Jae Seung YU, Seoul (KR); Gu Won SEON, Seoul (KR)

(73) Assignee: SEMES CO., LTD., Cheonan-si, Chungcheongnam-do (KR)

(21) Appl. No.: 18/792,771

(22) Filed: Aug. 2, 2024

(30) Foreign Application Priority Data
Aug. 16, 2023 (KR) 10-2023-0106627

(51) Int. Cl. H01L 21/033; H01L 21/324; H01L 21/67

(52) U.S. Cl. CPC H01L 21/0337; H01L 21/324; H01L 21/67109

(57) ABSTRACT

Disclosed is a substrate processing method including: a substrate loading operation of loading a substrate into a processing space provided by a body; a heating operation of placing the substrate, which has been loaded into the processing space, on a heating chuck and heating the substrate; and an atmosphere changing operation of changing an atmosphere of the processing space, in which the atmosphere changing operation includes: a gas discharging operation of injecting atmosphere changing gas in a state where the substrate is located closer to a baffle than in the heating operation, in which the baffle is provided on a top side of the heating chuck to face the heating chuck and injects the atmosphere changing gas; and a substrate lowering operation of lowering and placing the substrate onto the heating chuck while maintaining the injection of the atmosphere changing gas.

### CROSS-REFERENCE TO RELATED APPLICATIONS

This application claims priority to and the benefit of Korean Patent Application No. 10-2023-0106627 filed in the Korean Intellectual Property Office on Aug. 16, 2023, the entire contents of which are incorporated herein by reference.

### TECHNICAL FIELD

The present invention relates to a substrate processing method, a manufacturing method, and a substrate processing apparatus.

### BACKGROUND ART

In order to manufacture a semiconductor device, various processes, such as cleaning, deposition, photography, etching, and ion implantation, are performed. Among these processes, the photography process may include an application process in which a photoresist liquid is applied to a substrate, such as a wafer, to form a photosensitive film, an exposure process in which a photosensitive film is irradiated with light to change the properties of the portion corresponding to the pattern, a development process in which the irradiated portions or the unirradiated portions are selectively removed, and the like.

The photography process may also include a bake process in which the substrate is heated to stabilize the photosensitive film formed on the substrate. The bake process may be performed before or after the exposure process, and after the development process. A soft bake performed before the exposure process removes the solvent that the photoresist film contains. Post Exposure Bake (PEB) performed after the exposure process flattens the photosensitive film and reduces standing waves on the surface of the photosensitive film. The hard bake performed after the development process removes the solvent and developer residue from the photosensitive film formed on the substrate. The bake process is performed in a bake chamber, which provides the space where the substrate is processed.

FIG. 1 is a flow chart of a typical bake process. In a typical bake process, a substrate is fed into a bake chamber (S1), the substrate is heated in the bake chamber (S2), and the substrate is removed when the heating of the substrate is complete (S3).

Recently, inorganic photoresist has been used as the photosensitive liquid supplied to the substrate as the lithography process adopts extreme ultraviolet photolithography technology. The inorganic photoresist is more affected by the atmosphere in the bake chamber during the bake process than the general photoresists. Therefore, when the inorganic photoresist is used, a technology for switching the atmosphere in the bake chamber where the bake process is performed, a technology for quickly switching the atmosphere, a technology for uniformly processing the substrate, and the like are required.

### SUMMARY OF THE INVENTION

The present invention has been made in an effort to provide a substrate processing method, a manufacturing method, and a substrate processing apparatus that are capable of effectively processing a substrate.

The present invention has also been made in an effort to provide a substrate processing method, a manufacturing method, and a substrate processing apparatus that are capable of quickly changing atmosphere of a processing space in which a bake process is performed during the bake process.

The present invention has also been made in an effort to provide a substrate processing method, a manufacturing method, and a substrate processing apparatus that are capable of minimizing the occurrence of deviations in processing by region of a substrate when atmosphere of a processing space in which a bake process is performed is changed.

The object of the present invention is not limited thereto, and other objects not mentioned will be clearly understood by those of ordinary skill in the art from the following description.

The object of the present invention is not limited thereto, and other objects not mentioned will be clearly understood by those of ordinary skill in the art from the following description.

An exemplary embodiment of the present invention provides a substrate processing method including: a substrate loading operation of loading a substrate into a processing space provided by a body; a heating operation of placing the substrate, which has been loaded into the processing space, on a heating chuck and heating the substrate; and an atmosphere changing operation of changing an atmosphere of the processing space, in which the atmosphere changing operation includes: a gas discharging operation of injecting atmosphere changing gas in a state where the substrate is located closer to a baffle than in the heating operation, in which the baffle is provided on a top side of the heating chuck to face the heating chuck and injects the atmosphere changing gas; and a substrate lowering operation of lowering and placing the substrate onto the heating chuck while maintaining the injection of the atmosphere changing gas.

According to the exemplary embodiment, the substrate lowering operation may include lowering the substrate at a speed at which a concentration of the atmosphere changing gas in a region above the substrate is maintained at a set concentration or more.

According to the exemplary embodiment, the substrate lowering operation may include lowering the substrate at a first speed when the atmosphere changing gas is supplied at a first flow rate, and lowering the substrate at a second speed greater than the first speed when the atmosphere changing gas is supplied at a second flow rate greater than the first rate.

According to the exemplary embodiment, the atmosphere changing operation may further include a substrate lifting operation of lifting the substrate such that a gap between the substrate and the baffle is a set gap.

According to the exemplary embodiment, the set gap may be a gap selected in a range of 1 mm to 5 mm.

According to the exemplary embodiment, the atmosphere changing gas may be gas selected from humidified air, carbon dioxide, and nitrogen.

According to the exemplary embodiment, the substrate processing method may further include a substrate unloading operation of unloading the substrate from the processing space, in which the atmosphere changing operation may be performed a plurality of times between the substrate loading operation and the substrate unloading operation.

According to the exemplary embodiment, the substrate processing method may further include a substrate unloading operation of unloading the substrate from the processing space, in which the heating operation is performed a plurality of times between the substrate loading operation and the substrate unloading operation.

According to the exemplary embodiment, the heating operation may include: a first heating operation performed before the atmosphere changing operation; and a second heating operation performed after the atmosphere changing operation, and the first heating operation and the second heating operation may heat the substrate at different temperatures.

According to the exemplary embodiment, a bake process including the heating operation and the atmosphere changing operation may be performed after an exposure process of emitting light onto a photosensitive film applied onto the substrate.

According to the exemplary embodiment, the photosensitive film may be formed of an inorganic photoresist.

Another exemplary embodiment of the present invention provides a manufacturing method including: an exposure process of emitting light to a photosensitive film formed on a wafer; a bake process of heating the wafer after the exposure process; and a cooling process of cooling the wafer after the bake process, in which the bake process includes: a loading operation of loading the wafer into a processing space provided by a body; a heating operation of placing the wafer, which has been loaded into the processing space, on a heating chuck and heating the substrate; and an atmosphere changing operation of changing an atmosphere of the processing space in a state where the processing space is closed.

According to the exemplary embodiment, the atmosphere changing operation may include a gas discharging operation of injecting atmosphere changing gas in a state where the wafer is located to be closer to a baffle than in the heating operation, in which the baffle may be provided on a top side of the heating chuck to face the heating chuck and injects the atmosphere changing gas.

According to the exemplary embodiment, the atmosphere changing operation may include a lowering operation of lowering and placing the wafer onto the heating chuck while maintaining the injection of the atmosphere changing gas.

According to the exemplary embodiment, the lowering operation may include lowering the wafer at a speed at which a concentration of the atmosphere changing gas in a region between the wafer and the baffle is maintained at a set concentration or more.

Still another exemplary embodiment of the present invention provides a substrate processing apparatus including: a body providing a processing space; a heating chuck for supporting and heating the substrate in the processing space; a gas supply unit for supplying gas to the processing space; a baffle located above the heating chuck, and for distributing gas supplied by the gas supply unit; and a controller, in which the heating chuck includes: a heating plate provided with a heater to heat the substrate; and a lift pin module for lifting the substrate, and the controller may control the lift pin module and the gas supply unit so that the gas supply unit discharges the atmosphere changing gas into the processing space to change an atmosphere of the processing space in a state where the lift pin module supports the substrate such that a gap between the substrate and the baffle is a set gap.

According to the exemplary embodiment, the controller may lower the substrate in a direction toward proximity to the heating chuck while maintaining the discharge of the atmosphere changing gas, in which a lowering speed of the substrate may be set at a speed at which the concentration of the atmosphere changing gas in a space between the substrate and the baffle is maintained at a set concentration or more.

According to the exemplary embodiment, the set gap may be a gap selected in a range of 1 mm to 5 mm.

According to the exemplary embodiment, the gas supply unit may include at least one of a first gas supply source supplying humidified air, a second gas supply source supplying carbon dioxide, and a third gas supply source supplying inert gas.

According to the exemplary embodiment, the body may include an upper body, and a lower body that is combined with the upper body to define the processing space, the substrate processing apparatus may include a lifting mechanism for lifting the upper body to open and close the processing space, and the controller may control the lifting mechanism and the gas supply unit such that the atmosphere changing gas is discharged in a state where the processing space is closed.

According to the exemplary embodiment of the present invention, it is possible to control the film applied on the substrate to be uniform.

Further, according to the exemplary embodiment of the present invention, it is possible to uniformly supply gas onto a substrate during a heating process.

Furthermore, according to the exemplary embodiment of the present invention, it is possible to uniformly exhaust gas supplied to the substrate during the heating process.

Furthermore, according to the exemplary embodiment of the present invention, it is possible to minimize the increase in the area occupied by the heating unit performing the heating process on the substrate.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a flow chart of a typical bake process.

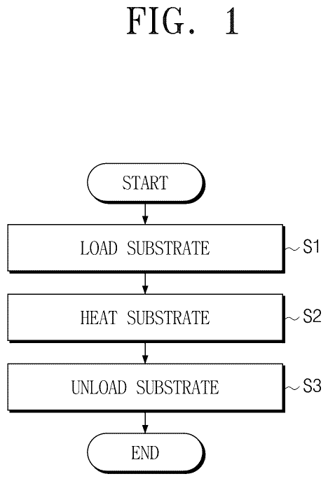

FIG. 2 is a perspective view schematically illustrating a substrate processing apparatus according to an exemplary embodiment of the present invention.

FIG. 3 is a cross-sectional view illustrating an applying block or a developing block of the substrate processing apparatus of FIG. 2.

FIG. 4 is a top plan view of the substrate processing apparatus of FIG. 2.

FIG. 5 is a diagram illustrating an example of a hand of the transfer robot of FIG. 4.

FIG. 6 is a top view schematically illustrating an example of a heat treating chamber of FIG. 4.

FIG. 7 is a front view of the heat treating chamber of FIG. 6.

FIG. 8 is a cross-sectional view illustrating a heating unit of FIG. 7.

FIG. 9 is a flow chart illustrating a substrate processing method according to an exemplary embodiment of the present invention.

FIG. 10 is a flow chart illustrating the operations of a bake process of FIG. 9.

FIG. 11 is a diagram illustrating the heating unit performing operation S10 of FIG. 10.

FIG. 12 is a diagram illustrating the heating unit performing operation S20 of FIG. 10.

FIG. 13 is a diagram illustrating the heating unit performing operation S30 of FIG. 10.

FIG. 14 is a diagram illustrating the heating unit performing operation S40 of FIG. 10.

FIG. 15 is a diagram illustrating the heating unit performing operation S50 of FIG. 10.

FIG. 16 is a diagram illustrating the heating unit performing operation S60 of FIG. 10.

FIG. 17 is a graph illustrating the time taken to change the atmosphere of each region of a substrate, and illustrating the Example of the present invention and a comparative example.

FIG. 18 is a graph illustrating the time for the concentration of atmosphere changing gas to reach a set concentration in a region above a substrate, and illustrating the Example of the present invention and a comparative example.

FIG. 19 is a graph illustrating the standard deviation of the concentration of atmosphere changing gas by region of the substrate, in a region above the substrate, and illustrating the Example of the present invention and a comparative example.

FIG. 20 is a flow chart illustrating operations of a bake process according to another exemplary embodiment of the present invention.

FIG. 21 is a flow chart illustrating operations of a bake process according to another exemplary embodiment of the present invention.

FIG. 22 is a diagram illustrating a heating unit according to another exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

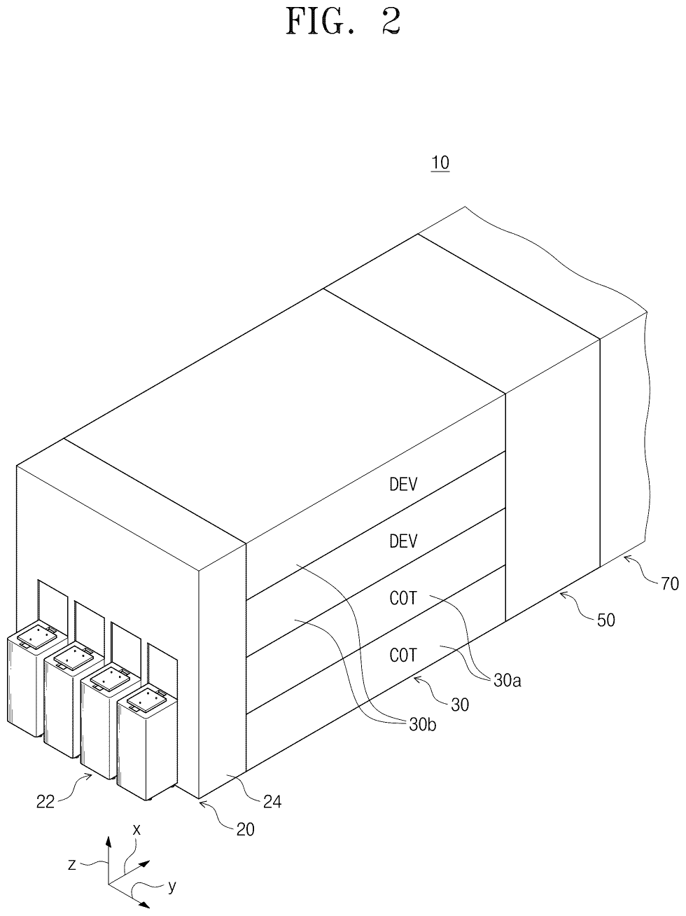

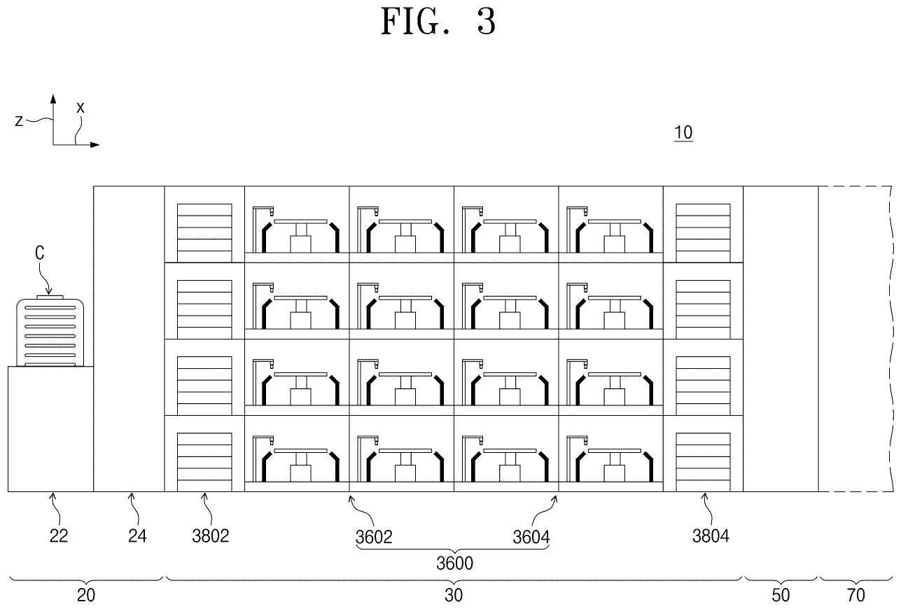

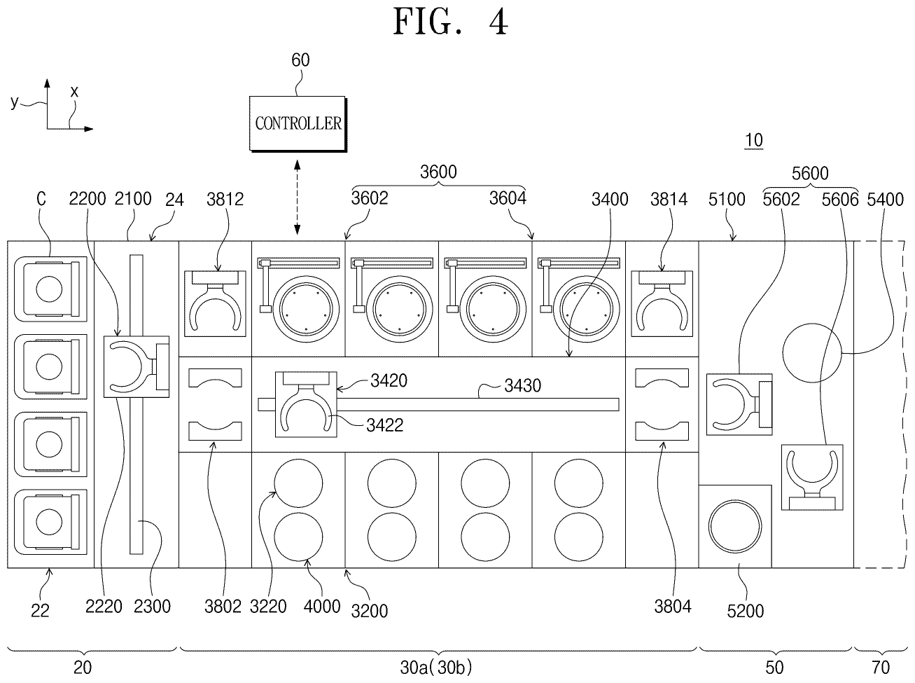

FIG. 2 is a perspective view schematically illustrating a substrate processing apparatus according to an exemplary embodiment of the present invention, FIG. 3 is a cross-sectional view illustrating an applying block or a developing block of the substrate processing apparatus of FIG. 2, and FIG. 4 is a top plan view of the substrate processing apparatus of FIG. 2.

Referring to FIGS. 2 to 4, a substrate processing apparatus 1 includes an index module 20, a treating module 30, and an interface module 40. According to the exemplary embodiment, the index module 20, the treating module 30, and the interface module 500 are sequentially arranged in a row. Hereinafter, a direction in which the index module 20, the treating module 30, and the interface module 40 are arranged is referred to as a first direction X, a direction perpendicular to the first direction 12 when viewed from above is referred to as a second direction Y, and a direction perpendicular to both the first direction X and the second direction Y is referred to as a third direction Z.

The index module 20 transfers the substrate W from a container C in which a substrate W is accommodated to the treating module 20, and accommodates the substrate W that has been completely treated in the treating module 20 in the container C. The longitudinal direction of the index module 20 is provided in the second direction Y. The index module includes a load port 22 and an index frame 24. Based on the index frame 24, the load port 22 is located at a side opposite to the treating module 30. The container C in which the substrates W are accommodated is placed in the load port 22. A plurality of load ports 22 may be provided, and the plurality of load ports 22 may be disposed along the second direction Y.

As the container C, an airtight container C, such as a Front Open Unified Pod (FOUP), may be used. The container C may be placed on the load port 22 by a transport means (not illustrated), such as an overhead transfer, an overhead conveyor, or an automatic guided vehicle, or an operator.

The index frame 24 includes an index chamber 2100. Inside the index chamber 2100, an index robot 2200 is provided. Within the index frame 2100, a guide rail 2300 is provided with a longitudinal direction in the second direction Y, and the index robot 2200 may be movably provided on the guide rail 2300. The index robot 2200 includes a hand 2220 on which the substrate W is placed, and the hand 2220 may be provided to be movable forward and backward directions, rotatable about the third direction Z and movable along the third direction Z.

The treating module 30 performs an application process and a development process on the substrate W. The treating module 30 includes an applying block 30a and a developing block 30b.

The applying block 30a performs an application process on the substrate W, and the developing block 30b performs a developing process on the substrate W. A plurality of applying blocks 30a is provided, and is provided to be stacked on each other. A plurality of developing blocks 30b is provided, and the developing blocks 30b is provided to be stacked on each other. According to the exemplary embodiment of FIG. 2, two applying blocks 30a are provided, and two developing blocks 30b are provided. The applying blocks 30a may be disposed under the developing blocks 30b. In one example, the two applying blocks 30a may perform the same process and be provided with the same structure as each other. Further, the two developing blocks 30b may perform the same process and may be provided in the same structure as each other.

The applying block 30a may include a heat treating chamber 3200, a transfer chamber 3400, a liquid treating chamber 3600, and a buffer chamber 3800.

The heat treating chamber 3200 is configured to perform a cooling process or bake process, on the substrate W. A plurality of heat treating chambers 3200 is provided. The heat treating chambers 3200 are arranged to be aligned along the first direction X. Some of the heat treating chambers 3200 may be arranged to be stacked on top of each other. The heat treating chambers 3200 are positioned on one side of the transfer chamber 3400. More details of the heat treating chambers 3200 will be described later.

The transfer chamber 3400 may be configured to transfer the substrate W between the heat treating chamber 3200, the liquid treating chamber 3600, and the buffer chamber 3800 within the applying block 30a.

The transfer chamber 3400 is provided with its longitudinal direction parallel to the first direction X. A transfer robot 3420 is provided to the transfer chamber 3420. The transfer robot 3420 transfers the substrate between the heat treating chamber 3200, the liquid treating chamber 3600, and the buffer chamber 3800. In one example, the transfer robot 3420 includes a hand 3422 on which the substrate W is placed, and the hand 3422 may be provided to be movable forward and backward directions, rotatable about the third direction Z and movable along the third direction Z. A guide rail 3430 of which a longitudinal direction is provided to be parallel to the first direction X is provided within the transfer chamber 3400, and the transfer robot 3420 may be provided to be movable on the guide rail 3430.

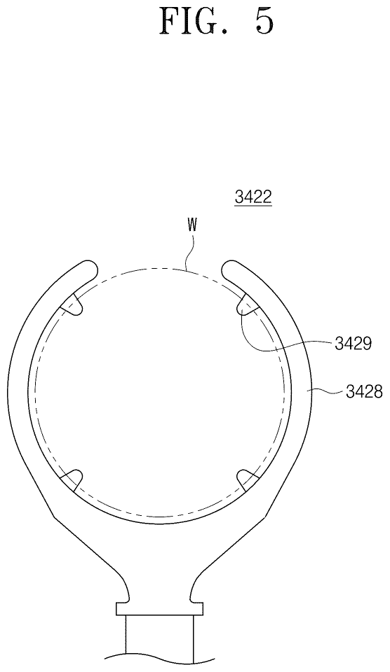

FIG. 5 is a diagram illustrating an example of the hand of the transfer robot of FIG. 4. Referring to FIG. 5, the hand 3422 includes a base 3428 and support protrusions 3429. The base 3428 may have a shape in which a portion of the circumference is cut away from the annular ring. The base 3428 has an inner diameter larger than a diameter of the substrate W. The support protrusion 3429 extends inwardly from the base 3428. A plurality of support protrusions 3429 is provided, and supports an edge region of the substrate W. In one example, four support protrusions 3429 may be provided at equal intervals.

Referring again to FIGS. 2 to 4, the liquid treating chambers 3600 are provided in a plurality. Some of the liquid treating chambers 3600 may be provided to be stacked on top of each other. The liquid treating chambers 3600 are disposed on opposite sides of the transfer chamber 3400. The liquid treating chambers 3600 are arranged side-by-side along the first direction X. Some of the liquid treating chambers 3600 are provided at locations adjacent to the index module 20. Hereinafter, the liquid treating chambers are referred to as front liquid treating chambers. Another some of the liquid treating chambers 3600 are provided at positions adjacent to the index module 50. Hereinafter, the liquid treating chambers are referred to as rear heat treating chambers.

The front liquid treating chamber 3602 applies a first liquid onto the substrate W, and the rear liquid treating chamber 3604 applies a second liquid onto the substrate W. The first liquid and the second liquid may be different types of liquid. In one exemplary embodiment, the first liquid is an anti-reflective film and the second liquid is an inorganic photoresist. The inorganic photoresist may be applied on the substrate W to which an antireflective film has been applied. Optionally, the first liquid may be an inorganic photoresist and the second liquid may be an antireflective film. In this case, the anti-reflective film may be applied to the substrate W on which the inorganic photoresist is applied. Optionally, the first liquid and the second liquid may be the same type of liquid, and they may both be inorganic photoresist.

The buffer chambers 3800 are provided in a plurality. Some of the buffer chambers 3800 are disposed between the index module 20 and the transfer chamber 3400. Hereinafter, the foregoing buffer chambers are referred to as front buffers 3802. The front buffers 3802 are provided in a plurality and are stacked on top of each other along an up and down direction. Another some of the buffer chambers 3802 and 3804 is disposed between the transfer chamber 3400 and the interface module 50. Hereinafter, the foregoing buffer chambers are referred to as rear buffers 3804. The rear buffers 3804 are provided in a plurality and are stacked on top of each other along an up and down direction. The front buffers 3802 and the rear buffers 3804 temporarily store a plurality of substrates W.

A front buffer robot 3812 is configured to transfer the substrate W between the front buffers 3802. A rear buffer robot 3814 is configured to transfer the substrate W between the rear buffers 3804. The front buffer robot 3812 includes a hand installed on a side of the front buffer 3802 and configured to be moveable along the third direction Z. Similarly, the back buffer robot 3814 includes a hand installed on a side of the back buffer 3804 and configured to be movable along the third direction Z.

The substrate W stored in the front buffer 3802 is loaded or unloaded by the index robot 2200 and the transfer robot 3420. The substrate W stored in the rear buffer 3804 is loaded or unloaded by the transfer robot 3420 and the first robot 4602.

The developing block 30b includes a heat treating chamber 3200, a transfer chamber 3400, and a liquid treating chamber 3600. The heat treating chamber 3200, the transfer chamber 3400, and the liquid treatment chamber 3600 of the developing block 30b are provided in a substantially similar structure and arrangement to the heat treating chamber 3200, the transfer chamber 3400, and the liquid treatment chamber 3600 of the applying block 30a, and will not be described herein. However, in the developing block 30b, all of the liquid treating chambers 3600 supply a developer to the developing chamber 3600 developing the substrate in the same way.

The interface module 50 connects the treating module 300 to an external exposing device 70. The interface module 50 includes an interface frame 5100, an additional process chamber 5200, an interface buffer 5400, and a transfer member 5600. The exposing device 70 may be a device that performs an exposure process by irradiating the substrate W on which a photosensitive film is formed with EUV.

A top end of the interface frame 5100 may be provided with a fan filter unit forming a downward airflow therein. The additional process chamber 5200, the interface buffer 5400, and the transfer member 5600 are disposed inside the interface frame 5100.

The additional processing chamber 5200 may perform a predetermined additional process before the substrate W, which has been completely processed in the applying block 30a, is loaded into the exposing device 70. Optionally, the additional processing chamber 5200 may perform a predetermined additional process before the substrate W, which has been completely processed in the exposing block 70, is loaded into the developing block 30b.

According to one example, the additional process may be an edge exposure process of exposing an edge region of the substrate W, a top surface cleaning process of cleaning the top surface of the substrate W, or a bottom surface cleaning process of cleaning the bottom surface of the substrate W.

A plurality of additional process chambers 5200 is provided, and may be provided to be stacked on each other. All of the additional process chambers 520 may be provided to perform the same process. Optionally, some of the additional process chambers 520 may be provided to perform different processes.

The interface buffer 5400 provides a space in which the substrate W transferred between the applying block 30a, the additional process chamber 5200, the exposing device 70, and the developing block 30b temporarily stays during the transfer. A plurality of interface buffers 5400 is provided, and the plurality of interface buffers 5400 may be provided to be stacked on each other.

According to the example, the additional process chamber 5200 may be disposed on one side of the transfer chamber 3400 based on an extended line in the longitudinal direction of the transfer chamber 3400 and the interface buffer 530 may be disposed on the other side thereof.

The transfer member 5600 provides the substrate W between the applying block 30a, the additional process chamber 5200, the exposing device 70, and the developing block 30b. The transfer member 380 may be provided as one robot or a plurality of robots.

According to one example, the transfer member 5600 includes a first robot 5602 and a second robot 5606. The first robot 5602 may be provided to transfer the substrate W between the applying block 30a, the additional processing chamber 5200, and the interface buffer 5400, the interface robot 4606 may be provided to transfer the substrate W between the interface buffer 5400 and the exposing device 70, and the second robot 5604 may be provided to transfer the substrate W between the interface buffer 5400 and the developing block 30b.

The first robot 5602 and the second robot 5602 each include a hand on which the substrate W is placed, and the hand may be provided to be movable forward and backward directions, rotatable about an axis parallel to the third direction Z, and movable along the third direction Z.

The hands of the index robot 2200, the first robot 5602, and the second robot 5606 may all be provided with the same shape as the hands 3420 of the transfer robots 3420 and 3424. Optionally, the hand of the robot that directly exchanges the substrate W with the transfer plate 3240 of the heat treatment chamber may be provided with the same shape as the hands 3420 of the transfer robots 3420 and 3424, while the hands of the remaining robots may be provided with a different shape from the shape of the hand 3420.

According to the exemplary embodiment, the index robot 2200 is provided to directly exchange the substrate W with the heating unit 3200 of the front heat treating chamber 4000 provided to the coating block 30a.

Further, the transfer robots 3420 provided to the applying block 30a and the developing block 30b may be provided to directly exchange the substrate W with the transfer plate 3240 located in the heat treating chamber 3200.

The controller 60 may control the substrate processing apparatus 10. The controller 60 may control the configurations of the substrate processing apparatus 10.

Further, the controller 60 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

In the following, the heat treating chamber 3200 according to the exemplary embodiment of the present invention will be described in detail.

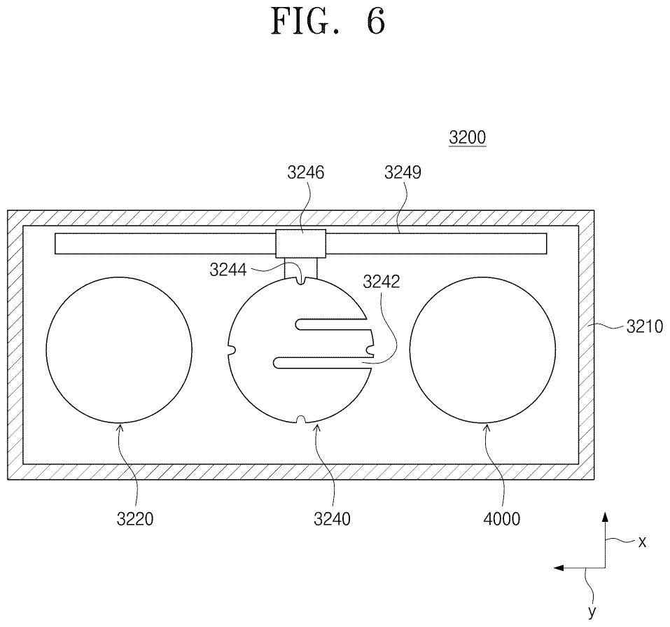

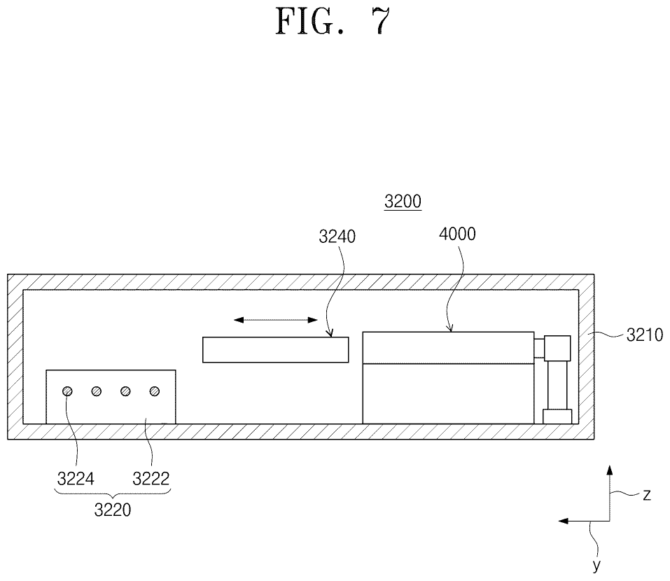

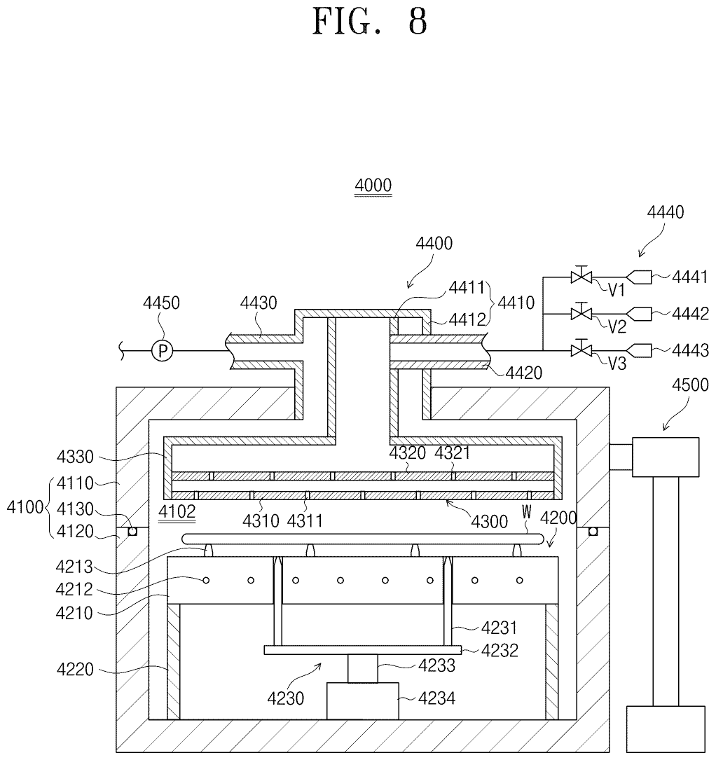

FIG. 7 is a front view of the heat treating chamber of FIG. 6, and FIG. 8 is a cross-sectional view illustrating a heating unit of FIG. 7.

Referring to FIGS. 7 and 8, the heat treating chamber 3200 includes a housing 3210, a cooling unit 3220, a heating unit 4000, and a transfer plate 3240.

The housing 3210 is provided in the shape of a generally rectangular parallelepiped. An entrance opening (not illustrated) through which the substrate W enters and exits is formed on a lateral wall of the housing 3210. The entrance opening may remain open. Optionally, a door (not illustrated) may be provided to open and close the entrance opening. The cooling unit 3220, the heating unit 4000, and the transfer plate 3240 are provided within the housing 3210. The cooling unit 3220 and the heating unit 4000 are provided side-by-side along the second direction Y. According to the example, the cooling unit 3220 may be located closer to the transfer chamber 3400 than the heating unit 4000.

The cooling unit 3220 includes a cooling plate 3222. The cooling plate 3222 may have a generally circular shape when viewed from above. A cooling passage 3224 is formed in the cooling plate 3222. A cooling fluid may flow in the cooling passage 3224.

The transfer plate 3240 is provided in a substantially disk shape, and has a diameter corresponding to that of the substrate W. A notch 3240 is formed at the edge of the transfer plate 3244. The notch 3244 may have a shape corresponding to a protrusion 3429 formed on the hand 3420 of the transfer robot 3420. In addition, the notches 3244 are provided in a number corresponding to the number of protrusions 3429 formed on the hand 3422, and are formed at positions corresponding to the protrusions 3429.

In a position where the hand 3422 and the transfer plate 3240 are aligned in an up-and-down direction, when the up-and-down position of the hand 3420 and the transfer plate 3240 is changed, a transfer of the substrate W between the hand 3422 and the transfer plate 3240 is performed. The transfer plate 3240 is mounted on the guide rail 3249 and may transfer the substrate W between the cooling unit 3220 and the heating unit 4000 along the guide rail 3249 by the driver 3246.

A plurality of slit-shaped guide grooves 3242 is provided in the transfer plate 3240. The guide groove 3242 extends from the distal end of transfer plate 3240 to the interior of transfer plate 3240. The longitudinal direction of the guide groove 3242 is provided along the second direction 14, and the guide grooves 3242 are positioned while being spaced apart from each other along the first direction 12. The guide groove 3242 prevents the transfer plate 3240 and the lift pins 3238 from interfering with each other when the substrate W is transferred between the transfer plate 3240 and the heating unit 4000.

The heating unit 4000 is provided as a device for heating the substrate to a temperature higher than room temperature. The heating unit 4000 may perform a soft bake process to heat the substrate W before an exposure process is performed on the substrate W, a Post Exposure Bake (PEB) process to heat the substrate W after an exposure process is performed on the substrate W, or a hard bake process to heat the substrate W after a development process is performed on the substrate W.

FIG. 8 is a cross-sectional view illustrating the heating unit of FIG. 7.

Referring to FIG. 8, the heating unit 4000 may include a body 4100, a heating chuck 4200, a baffle assembly 4300, a gas supply part 4400, and a lifting mechanism 4500.

The body 4100 may provide a processing space 4102. The body 4100 may include an upper body 4110, a lower body 4120, and a sealing member 4130. The lower body 4120 may have a barrel shape with an open top. The upper body 4110 may have a cover shape that covers the top portion of the lower body 4120. The upper body 4110 may have a barrel shape with an open bottom. The upper body 4110 and the lower body 4120 may be combined with each other to define the processing space 4102, which is a space in which the substrate W, which may be a wafer, is processed.

Any one of the upper body 4110 and the lower body 4120 may be configured to be moveable relative to the other. For example, the upper body 4110 may be configured to be movable in an up-and-down direction by the lifting mechanism 4500, which may be a drive device including a motor, cylinder, or the like. By providing the upper body 4110 to be movable in the up-and-down direction, the processing space 4102 may be open or closed.

When the substrate W is introduced into the processing space 4102, the upper body 4110 may rise to open the processing space 4102, and when the bake process is performed on the substrate W, the upper body 4110 may lower to close the processing space 4102.

The sealing member 4130 may be an O-ring that may fill a gap that may be generated between the upper body 4110 and the lower body 4120. The sealing member 4130 may have a substantially circular ring shape. The sealing member 4130 may be made of an engineering plastic that has certain elasticity and may withstand damage from the external environment, such as heat and humidity.

The heating chuck 4200 may heat the substrate W. The heating chuck 4200 may support the substrate W. The heating chuck 4200 may include a heating plate 4210, a support member 4220, and a lift pin module 4230.

The heating plate 4210 may heat the substrate W. The heating plate 4210 may be formed of a material with good thermal conductivity. For example, the heating plate 4210 may be formed of a metallic material, such as aluminum. The heating plate 4210 may have a substantially disk-like shape when viewed from top to bottom. The heating plate 4210 may be provided with a disk shape having a diameter equal to or larger than the substrate W.

A heater 4212 may be installed on the heating plate 4210. The heater 4212 may be installed by being buried inside the heating plate 4210. Alternatively, the heater 4212 may be installed by being attached to the bottom surface of the heating plate 4210. The heater 4212 may be a heating element that receives power from the outside to generate heat. For example, the heater 4212 may be a resistive heating element.

In addition, support pins 4213 may be installed on the top surface of the heating plate 4210. The support pins 4213 may be provided in plurality. The support pins 4213 may prevent the top surface of the heating plate 4210 and the bottom surface of the substrate W from being in direct contact. When the bottom surface of the substrate W is in direct contact with the heating plate 4210, the bottom surface of the substrate W may be scratched. In some cases, the bottom surface of the substrate W may also generate particles when the bottom surface of the substrate W is in direct contact with the heating plate 4210. The support pins 4213 are configured to prevent direct contact between the bottom surface of the substrate W and the top surface of the heating plate 4210, but allow for a very narrow gap between the bottom surface of the substrate W and the top surface of the heating plate 4210.

The support member 4220 may support the heating plate 4210. The support member 4220 may have a generally cylindrical shape with an open top portion and an open bottom portion.

A lift pin module 4230 may move the substrate W in an up-and-down direction. The lift pin module 4230 may include a plurality of lift pins 4231, a lift plate 4232, a lift shaft 4333, and a lift driver 4234.

The lift pins 4231 may have a pin shape extending in an up-and-down direction, and may be inserted into pin holes formed in the heating plate 4210, respectively. The lift pins 4231 may be installed on the top surface of the lift plate 4232. The lift plate 4232 may have a plate shape. The lift driver 4234 may be a motor or a pneumatic/hydraulic cylinder. The lift driver 4334 may move the lift shaft 4233, which is connected to a lower portion of the lift plate 4232, in an up-and-down direction. The lift plate 4232 may move the lift pin 4231 in an up-and-down direction by movement of the lift shaft 4233.

The baffle assembly 4300 allows gas supplied by the gas supply part 4400, which will be described later, to be uniformly distributed throughout the processing space 4102. The baffle assembly 4300 may include an upper baffle 4310, a lower baffle 4320, and a baffle support member 4330.

First holes 4311 may be formed in the upper baffle 4310 and second holes 4321 may be formed in the lower baffle 4320. When viewed from above, the first hole 4311 and the second hole 4321 may be formed such that they do not overlap each other. The upper baffle 4310 may be installed above the lower baffle 4320. The baffle support member 4330 may have a cylindrical shape with an open lower portion and an open upper center region.

A diameter of the outer surface of the baffle support member 4330 may have a smaller diameter than a diameter of an inner wall of the upper body 4110. Accordingly, the space between the baffle support member 4330 and the upper body 4110 may function as a gas exhaust port through which gas exhaust occurs via a gas exhaust part 4450 described later.

The gas supply part 4400 is configured to supply gas to the processing space 4102 and to exhaust the gas supplied to the processing space 4102/fumes generated in the processing space 4102 to the outside.

The gas supply part 4400 may include a gas block 4410, a gas supply pipe 4420, a gas exhaust pipe 4430, a gas supply part 4440, and the gas exhaust part 4450.

The gas block 4400 may provide a pathway for supplying gas to the processing space 4102 and exhausting the atmosphere of the processing space 4102. The gas block 4400 may include an inner body 4411 and an outer body 4412. The outer body 4412 may have a generally cap-like shape, and may be fixedly installed in a form that is inserted into an upper center region of the upper body 4110. The inner body 4411 may be installed in the inner region of the outer body 4412 and may have a generally tubular shape.

The inner space of the inner body 4411 may be connected with the gas supply pipe 4420, and the space between the outer body 4412 and the inner body 4411 may be connected with the gas exhaust pipe 4430. Accordingly, the inner space of the inner body 4411 may function as a gas supply path through which gas is supplied, and the space between the outer body 4412 and the inner body 4411 may function as a gas exhaust path through which gas is exhausted.

The gas supply pipe 4420 may receive gas from a gas supply part 4400.

The gas supply part 4400 may be configured to allow different types of gas to be supplied to the gas supply part 4400. The gas supplied by the gas supply part 4400 may be atmosphere changing gas to change the atmosphere of the processing space 4102. The gas supply part 4400 may include a first gas supply source 4441 for supplying humidified air, a second gas supply source 4442 for supplying carbon dioxide, and a third gas supply source 4443 for supplying inert gas, such as nitrogen.

A first valve V1 may be configured to selectively supply humidified air to the gas supply pipe 4420, or to regulate the amount of humidified air supplied to the gas supply pipe 4420 per unit time. The first valve V1 may be an automatic valve, or may be a flow regulating valve.

A second valve V2 may be configured to selectively supply carbon dioxide to the gas supply pipe 4420, or to regulate the amount of carbon dioxide supplied to the gas supply pipe 4420 per unit time. The second valve V2 may be an automatic valve, or may be a flow regulating valve.

A third valve V3 may be configured to selectively supply inert gas to the gas supply pipe 4420, and/or to regulate the amount of inert gas supplied to the gas supply pipe 4420 per unit time. The third valve V3 may be an automatic valve, or may be a flow regulating valve.

The gas exhaust part 4450 may be connected to the gas exhaust pipe 4430 to vent the gas supplied to the processing space 4102 and fumes that may be generated in the processing space 4102 to the outside of the processing space 4102. The gas exhaust part 4450 may be a pump.

Hereinafter, a substrate processing method according to an exemplary embodiment of the present invention will be described. The substrate processing method according to the exemplary embodiment of the present invention may be a semiconductor device manufacturing method for manufacturing a semiconductor device. Further, to perform the substrate processing method described herein, the controller 60 may control the configurations of the substrate processing apparatus 10.

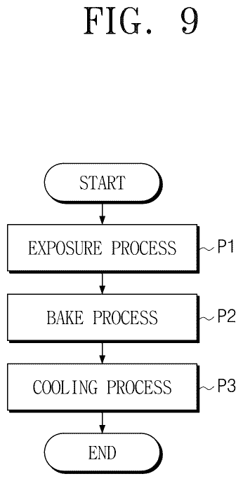

FIG. 9 is a flow chart illustrating a substrate processing method according to an exemplary embodiment of the present invention.

The substrate processing method according to the exemplary embodiment of the present invention may include an exposure process P1, a bake process P2, and a cooling process P3. The exposure process P1, the bake process P2, and the cooling process P3 may be performed sequentially. The exposure process P1 may be performed in the exposing device 70 described above. The bake process P2 may be performed in the heating unit 4000 described above. The cooling process P3 may be performed in the cooling unit 3220 described above.

The exposure process P1 may be a process of emitting light onto a photosensitive film formed on the substrate W. The light emitted to the substrate W in the exposure process P1 may be light having a wavelength of extreme ultraviolet (EUV).

The bake process P2 may be a process for heating the substrate W, and the cooling process P3 may be a process for cooling the substrate W heated in the bake process P2.

In the example described above, the substrate processing method is described as including the exposure process P1, the bake process P2, and the cooling process P3, but before the exposure process P1 is performed, an application process may be performed in the liquid treating chamber 3600 to apply an inorganic photoresist. Further, after the exposure process P1 is performed, a development process to develop the photosensitive film may be performed in the liquid treating chamber 3600.

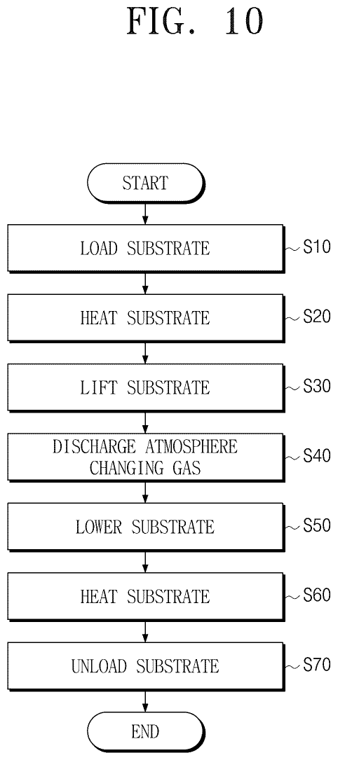

FIG. 10 is a flow chart illustrating the operations of the bake process of FIG. 9.

Referring to FIG. 10, the bake process according to the exemplary embodiment of the present invention may be performed sequentially from operation S10 to operation S70.

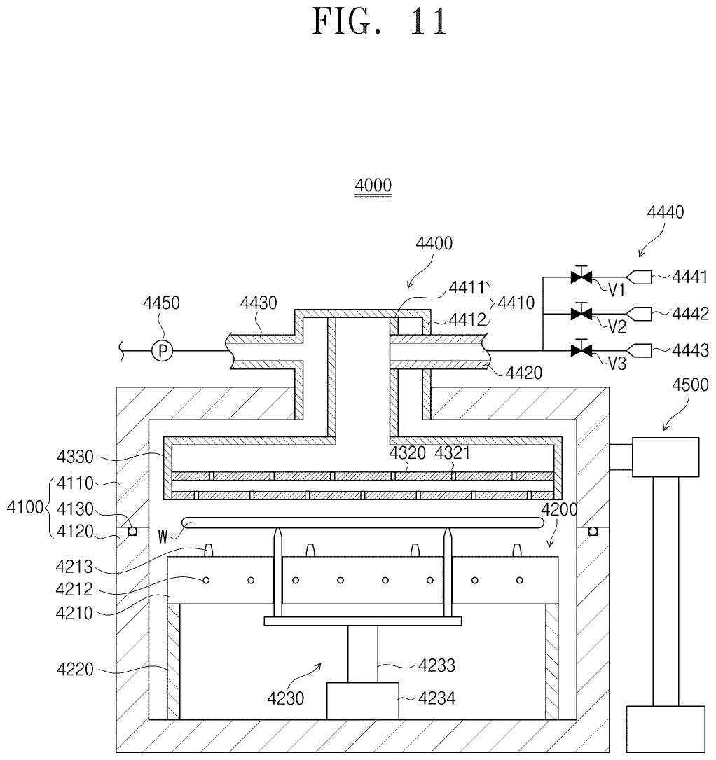

FIG. 11 is a diagram illustrating the heating unit performing operation S10 of FIG. 10. Referring to FIGS. 10 and 11, in operation S10, the substrate W may be loaded into the processing space 4102. Step S10 may be a substrate loading operation. In operation S10, the lifting mechanism 4500 may move the upper body 4110 in an upward direction to open the processing space 4102, and the lift pin 4231 may be pinned up. When the substrate W is loaded into the processing space 4102, the lifting mechanism 4500 may move the upper body 4110 in a downward direction to close the processing space 4102. The lift pin module 4230 may then lower the substrate W onto the heating chuck 4200 with the lift pin 4231.

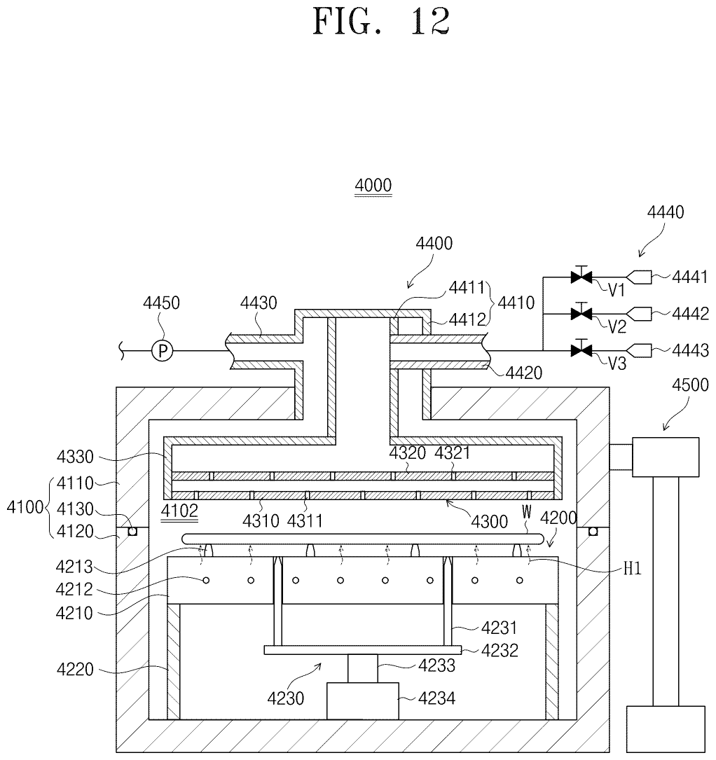

FIG. 12 is a diagram illustrating the heating unit performing operation S20 of FIG. 10. Referring to FIGS. 10 and 12, in operation S20, the substrate W placed on the heating chuck 4200 may be heated. Step S20 may be a first substrate heating operation. In operation S20, the heating chuck 4200 may generate heat to heat the substrate W. For example, the heater 4212 provided in the heating chuck 4200 may generate heat, the temperature of the heating plate 4210 may increase, and the heating plate 4210 may transfer heat H1 of a first temperature to the substrate W placed on the support pin 4213. In operation S20, the processing space 4102 may not be supplied with any special atmosphere changing gas. Accordingly, the atmosphere in the processing space 4102 may be the same as a normal atmospheric condition.

Step S20 may also be a pre-heating operation to raise the temperature of the substrate W to a set temperature before a second substrate heating operation is performed to heat the substrate W after the atmosphere changing gas is later injected into the processing space 4102.

In the following, the atmosphere changing operation will be described. Step S30, operation S40, and operation S50 may be operations included in the atmosphere changing operation. The atmosphere changing operation may include changing the atmosphere of the processing space 4102. For example, the atmosphere changing operation may be an operation of changing a concentration ratio of gas that the atmosphere of the processing space 4102 includes.

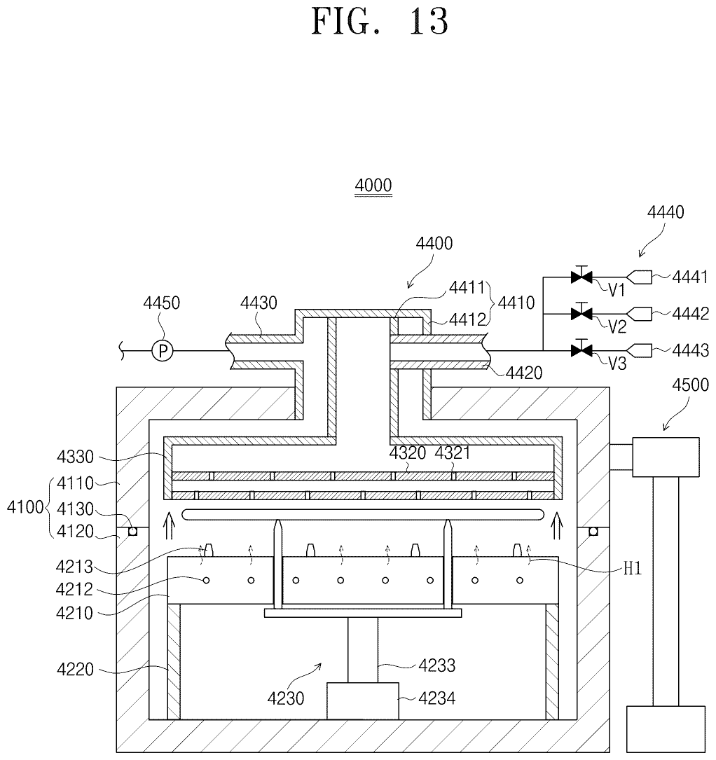

FIG. 13 is a diagram illustrating the heating unit performing operation S30 of FIG. 10. Referring to FIGS. 10 and 13, in operation S30, the lift pin module 4230 may lift the substrate W to lift the substrate W to a position close to the baffle assembly 4300. Step S30 may be a substrate lifting operation. Step S30 includes decreasing the gap between the top surface of the substrate W and the bottom surface of the lower baffle 4310 to a set gap D. The set gap may be a selected gap in the range of 1 mm to 5 mm. By decreasing the gap between the top surface of the substrate W and the lower baffle 4310 in operation S30, the top surface of the substrate W, and more specifically, the volume between the substrate W and the lower baffle 4310, may be reduced.

At this time, the heater 4212 of the heating chuck 4200 may continue to heat. This is to prevent the heater 4212 from stopping heating and causing the temperature of the heating plate 4210 to decrease. This is because when the substrate W is placed on the heating plate 4210 after the heating plate 4210 has cooled down, the photosensitive film formed on the substrate W may not be baked properly.

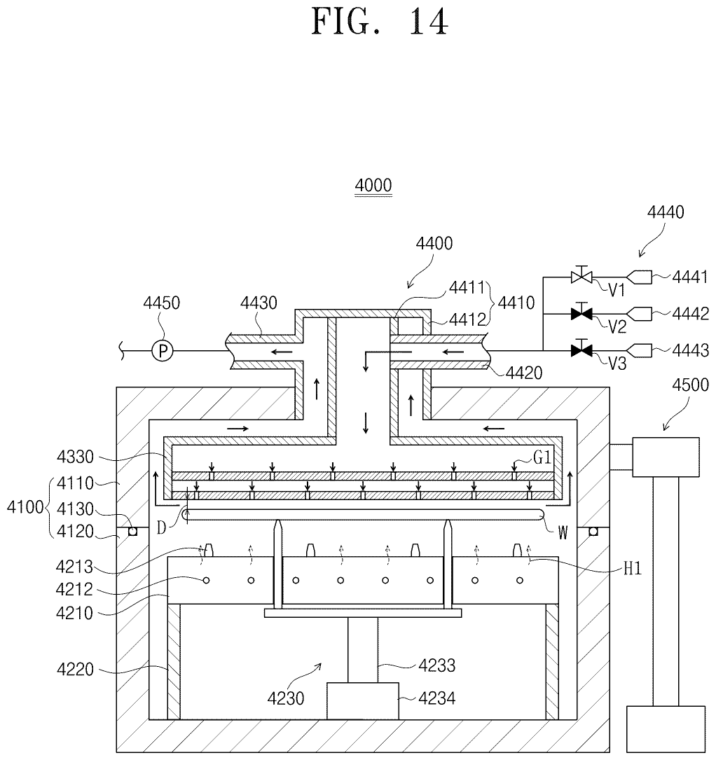

FIG. 14 is a diagram illustrating the heating unit performing operation S40 of FIG. 10. Referring to FIGS. 10 and 14, after the gap between the substrate W and the lower baffle 4310 reaches the set gap D, the gas supply part 4400 may supply atmosphere changing gas to the processing space 4102. Step S40 may be a gas discharging operation. The atmosphere changing gas may be any one selected from a variety of gas that the gas unit 4200 may supply. For example, as illustrated in FIG. 14, the first valve V1 may be opened and the first gas supply source 4441 may supply humidified air to the processing space 4102.

In this case, the volume of the space above the substrate W is very small due to the lifting of the substrate W. Therefore, the atmosphere change in the space above the substrate W, and more specifically the space between the substrate W and the lower baffle 4310, may occur very quickly. Since the photosensitive film formed on the surface above the substrate W is strongly affected by the atmosphere of the space above the substrate W, and since the atmosphere changing gas is supplied while the volume of the space above the substrate W is very small, the atmosphere change of the space above the substrate W may be accomplished very quickly. Step S40 may be performed when the concentration of the atmosphere changing gas in the space above the substrate W reaches a set concentration.

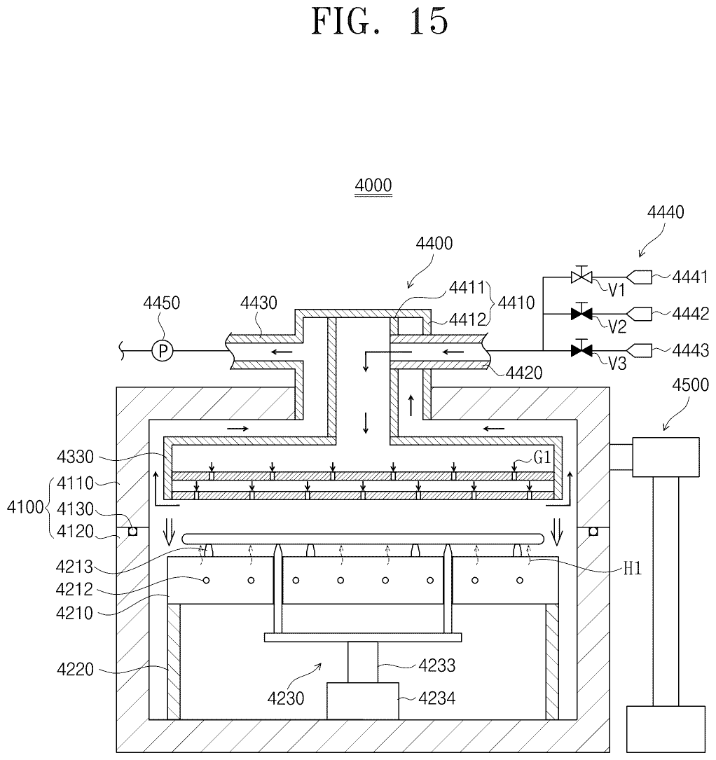

FIG. 15 is a diagram illustrating the heating unit performing operation S50 of FIG. 10. Referring to FIGS. 10 and 15, while the substrate W is lifted, the substrate W may be lowered to perform a subsequent heating operation on the substrate W after the atmosphere changing gas is discharged. Step S50 may be a substrate lowering operation. During the substrate lowering operation, when a lowering speed of the substrate W is too fast, the concentration of the atmosphere changing gas supplied to the space above the substrate W may change. For example, when the lower speed of the substrate W is too fast, the concentration of the atmosphere changing gas in the space above the substrate W may be lowered. When the concentration of the atmosphere changing gas is lowered, the atmosphere in the processing space 4102 for processing the substrate W may not remain constant. This may interfere with uniform processing of the substrate W.

Accordingly, in the substrate lowering operation according to the exemplary embodiment of the present invention, the gas supply part 4400 may lower the substrate W onto the heating chuck 4200 while maintaining a supply of the atmosphere changing gas, but lowering the substrate W at a predetermined set speed. In this case, the set speed may be a speed at which the concentration of the atmosphere changing gas in the region above the substrate W may be maintained at a set concentration or more. The set speed may be memorized in advance in the controller 60 through a previously performed experiment or simulation.

The set concentration may be varied depending on the recipe required to process the substrate W. For example, the set concentration may be a concentration selected from a range of 0 to 100%. For example, when the substrate W is first loaded into the processing space 4102, the processing space 4102 may have atmosphere of a normal atmospheric condition. Subsequently, in the atmosphere changing operation, the atmosphere changing gas, such as nitrogen gas, may be supplied so that the concentration of nitrogen gas in the processing space 4102 is 100%.

During the substrate lowering operation, the lower speed of the substrate W may vary depending on the supply flow rate of the atmosphere changing gas from the gas supply part 4400. For example, when the gas supply part 4400 supplies a first flow rate per unit time of the atmosphere changing gas, the substrate W may be lowered at a first speed, and when the gas supply part 4400 supplies a second flow rate per unit time of the atmosphere changing gas, the substrate W may be lowered at a second speed. The second flow rate may be a flow rate greater than the first flow rate, and the second speed may be a speed greater than the first speed.

The control setting values, such as the supply flow rate per unit time of the gas and the lowering speed of the substrate W, for changing the atmosphere of the processing space 4102 to the set concentration, may be preset based on process data collected using a substrate-type sensor with a sensor for sensing gas concentration/humidity, and the like prior to processing the substrate W to be processed.

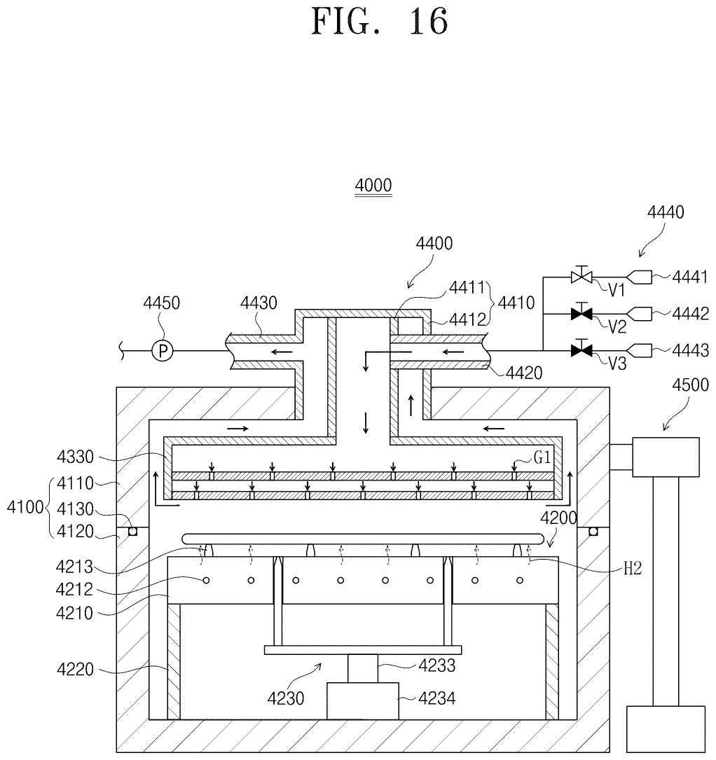

FIG. 16 is a diagram illustrating the heating unit performing operation S60 of FIG. 10. Referring to FIGS. 10 and 16, after operation S50 is completed, the substrate W may once again be placed on the heating chuck 4200. The heating chuck 4200 may heat the substrate W. Step S50 may be a second substrate heating operation. The heating chuck 4200 may heat the substrate W to a second temperature. The second temperature may be a different temperature from the first temperature, which is the temperature at which the substrate W is heated in the first substrate heating operation. Further, operation S50 may be performed in a state where the atmosphere of the processing space 4102 of the substrate W is changed.

Step S70 may include unloading the processed substrate W from the processing space 4102. Step S70 may be a substrate unloading operation. In operation S70, the lifting mechanism 4500 may open the processing space 4102, and the lift pin module 4230 may raise the substrate W.

Steps S20 to S60 described above may be performed successively in the state where the processing space 4102 is continuously closed. Thus, in the present invention, changing the atmosphere of the processing space 4102 may not cause the supplied gas in the processing space 4102 to leak into the interior space of the housing 3210.

Further, the heights by which the lift pin module 4230 raises the substrate W in operation S10 and operation S70 may be the same. However, the heights by which the substrate W is raised in operation S10 and operation S70 and the height by which the substrate W is raised in operation S30 may be different.

In the following, the effectiveness of the present invention will be described through the comparison between the example of the present invention and Comparative Examples. The Example may be the case where the substrate W is lifted during the atmosphere changing operation to decrease the gap between the substrate W and the lower baffle 4310. The Comparative Example may be the case where the substrate W is seated on the heating chuck 4200 during the atmosphere changing operation.

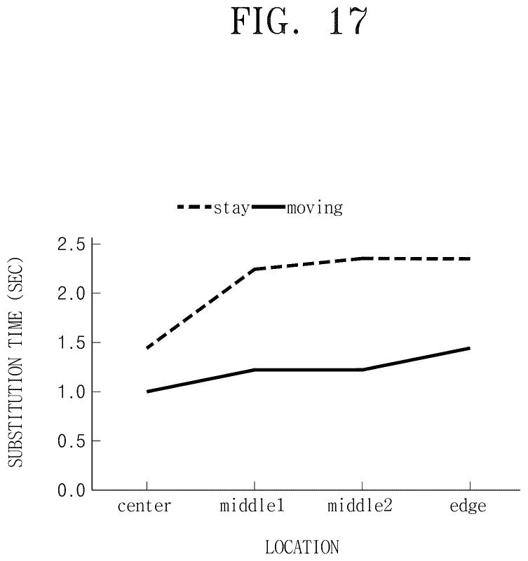

The Example is indicated by “moving” in the graphs of FIGS. 17 to 19, and the Comparative Example is indicated by “stay”.

FIG. 17 is a graph illustrating the time taken to change the atmosphere of each region of a substrate, and illustrating the Example of the present invention and the Comparative Example.

Referring to FIG. 17, the time required for the atmosphere change (substitution time) may mean the time for the concentration of the atmosphere changing gas in the space above the substrate W to reach a set concentration. As may be seen with reference to FIG. 17, it may be seen that the Example takes much less time to change the atmosphere than the Comparative Example. Furthermore, it may be seen that there is less variation in the time it takes for the concentration of the atmosphere changing gas to reach the set concentration in different regions of the substrate W. Thus, it may be seen that according to the Example of the present invention, the time required for the atmosphere change may be shortened and the uniformity of the processing by region of the substrate W may be improved.

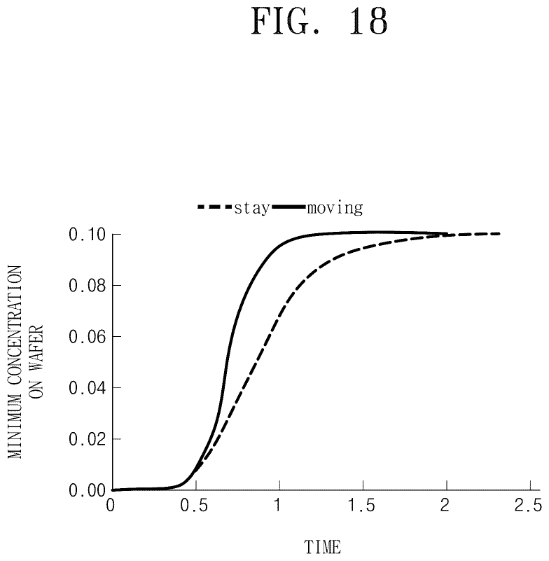

FIG. 18 is a graph illustrating the time for the concentration of atmosphere changing gas to reach a set concentration in the region above the substrate, and illustrating the Example of the present invention and the Comparative Example. The x-axis may be time (second), and the y-axis may be the concentration of the atmosphere changing gas. In FIG. 18, the set concentration may be 0.1 (that is, 10%). It may be seen that the time for the minimum concentration in the space above the substrate W to reach the set concentration is shorter in the Example than in the Comparative Example. Furthermore, the lowering of the substrate W may occur after 1 second. As illustrated in FIG. 18, it may be seen that the minimum concentration in the space above the substrate W remains 0.1 or more even when the substrate W is lowered.

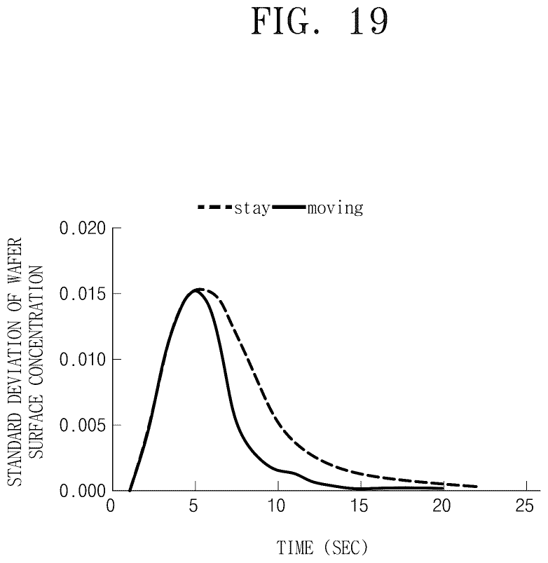

FIG. 19 is a graph illustrating the standard deviation of the concentration of atmosphere changing gas by region of the substrate in the region above the substrate, and illustrating the Example of the present invention and the Comparative Example.

Referring to FIG. 19, it may be seen that the standard deviation of the concentration of the atmosphere changing gas per region of the substrate W decreases faster in the Example than in the Comparison Example. In other words, it may be seen that in the Example of the present invention, the atmosphere of the processing space 4102 is quickly changed and the deviation of the concentration of the substrate W by region is quickly stabilized.

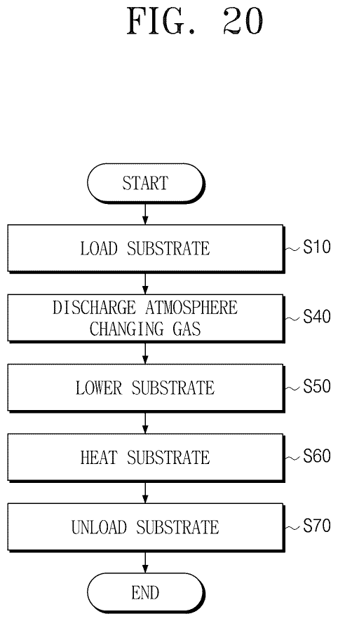

In the Example described above, the case where the substrate W is first heated, and then the substrate W is raised, and then the atmosphere changing gas is discharged has been described as an example, but the present invention is not limited thereto. As illustrated in FIG. 20, when the substrate W is loaded into the processing space 4102, the substrate W is lifted by the lift pin module 4230, so that the atmosphere of the processing space 4102 may be changed from an ambient state to a set atmosphere by immediately performing the gas discharging operation after the substrate loading operation.

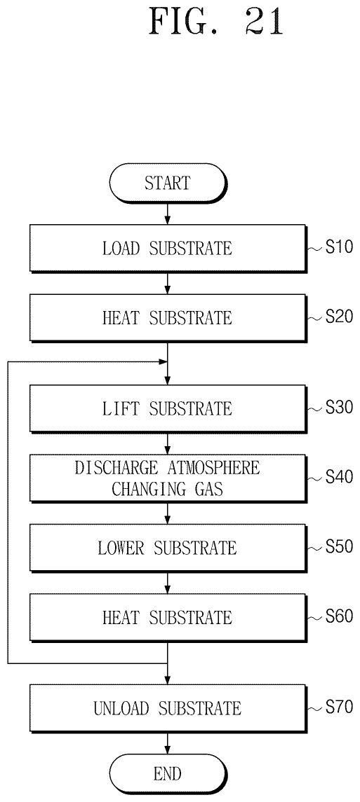

In the example described above, the case where the atmosphere changing operation is performed once has been described as an example, but the present invention is not limited thereto. For example, as illustrated in FIG. 21, after the substrate heating operation is completed, the atmosphere changing operation may be performed a preset number of times.

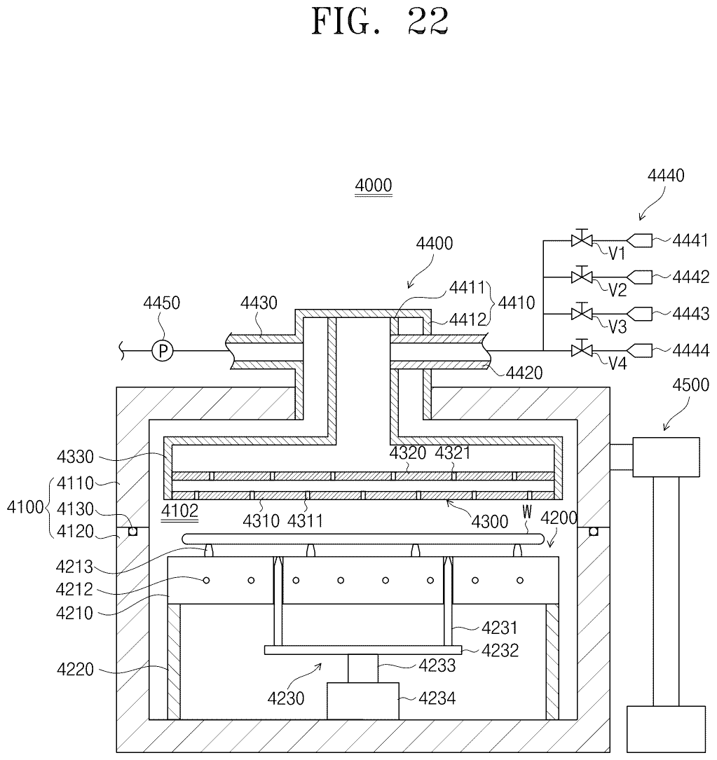

In the examples described above, the case where the cooling process P3 is performed in the cooling unit 3220 has been described as an example, but the present invention is not limited thereto. For example, as illustrated in FIG. 22, the gas supply part 4440 may further include a cooling gas supply source 4444 and a fourth valve V4. Accordingly, the cooling process P3 may be performed continuously in the processing space 4102 after the bake process P2 for the substrate W is completed in the processing space 4102. Further, during the cooling process P3, the lift fin module 4230 may supply cooling gas to the substrate W while the substrate W is lifted. The cooling gas may be selected from a variety of gas, but may be CDA or inert gas at room temperature.

In the example illustrated and described above, the case where any one selected from the gas that may be supplied by the gas supply part 4440 is supplied in the atmosphere changing operation has been described as an example, but the present invention is not limited thereto. For example, in the atmosphere changing operation, the gas supply part 4440 may also supply two or more types of gas to the processing space 4102.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

1. A substrate processing method comprising:
a substrate loading operation of loading a substrate into a processing space provided by a body;
a heating operation of placing the substrate, which has been loaded into the processing space, on a heating chuck and heating the substrate; and
an atmosphere changing operation of changing an atmosphere of the processing space,
wherein the atmosphere changing operation includes:
a gas discharging operation of injecting atmosphere changing gas in a state where the substrate is located closer to a baffle than in the heating operation, wherein the baffle is provided on a top side of the heating chuck to face the heating chuck and injects the atmosphere changing gas; and
a substrate lowering operation of lowering and placing the substrate onto the heating chuck while maintaining the injection of the atmosphere changing gas.

2. The substrate processing method of claim 1, wherein the substrate lowering operation includes lowering the substrate at a speed at which a concentration of the atmosphere changing gas in a region above the substrate is maintained at a set concentration or more.

3. The substrate processing method of claim 1, wherein the substrate lowering operation includes lowering the substrate at a first speed when the atmosphere changing gas is supplied at a first flow rate, and lowering the substrate at a second speed greater than the first speed when the atmosphere changing gas is supplied at a second flow rate greater than the first rate.

4. The substrate processing method of claim 1, wherein the atmosphere changing operation further includes a substrate lifting operation of lifting the substrate such that a gap between the substrate and the baffle is a set gap.

5. The substrate processing method of claim 4, wherein the set gap is a gap selected in a range of 1 mm to 5 mm.

6. The substrate processing method of claim 1, wherein the atmosphere changing gas is gas selected from humidified air, carbon dioxide, and nitrogen.

7. The substrate processing method of claim 1, further comprising:
a substrate unloading operation of unloading the substrate from the processing space,
wherein the atmosphere changing operation is performed a plurality of times between the substrate loading operation and the substrate unloading operation.

8. The substrate processing method of claim 1, further comprising:
a substrate unloading operation of unloading the substrate from the processing space,
wherein the heating operation is performed a plurality of times between the substrate loading operation and the substrate unloading operation.

9. The substrate processing method of claim 8, wherein the heating operation includes:
a first heating operation performed before the atmosphere changing operation; and
a second heating operation performed after the atmosphere changing operation, and
the first heating operation and the second heating operation heat the substrate at different temperatures.

10. The substrate processing method of claim 1, wherein a bake process including the heating operation and the atmosphere changing operation is performed after an exposure process of emitting light onto a photosensitive film applied onto the substrate.

11. The substrate processing method of claim 10, wherein the photosensitive film is formed of an inorganic photoresist.

12. A manufacturing method comprising:
an exposure process of emitting light to a photosensitive film formed on a wafer;
a bake process of heating the wafer after the exposure process; and
a cooling process of cooling the wafer after the bake process,
wherein the bake process includes:
a loading operation of loading the wafer into a processing space provided by a body;
a heating operation of placing the wafer, which has been loaded into the processing space, on a heating chuck and heating the substrate; and
an atmosphere changing operation of changing an atmosphere of the processing space in a state where the processing space is closed.

13. The manufacturing method of claim 12, wherein the atmosphere changing operation includes a gas discharging operation of injecting atmosphere changing gas in a state where the wafer is located to be closer to a baffle than in the heating operation, wherein the baffle is provided on a top side of the heating chuck to face the heating chuck and injects the atmosphere changing gas.

14. The manufacturing method of claim 13, wherein the atmosphere changing operation includes a lowering operation of lowering and placing the wafer onto the heating chuck while maintaining the injection of the atmosphere changing gas.

15. The manufacturing method of claim 14, wherein the lowering operation includes lowering the wafer at a speed at which a concentration of the atmosphere changing gas in a region between the wafer and the baffle is maintained at a set concentration or more.

16.-20. (canceled)
